(19) United States
(12) Patent Application Publication
(10) Pub. No.: US 2024/0070043 A1
(43) Pub. Date: Feb. 29, 2024

(54) METHOD AND STORAGE MEDIUM FOR DETECTING PERFORMANCE OF HARD DISKS

(71) Applicant: Fulian Precision Electronics (Tianjin) Co., LTD., Tianjin (CN)

(72) Inventors: WEI WEI, Tianjin (CN); JIE YUAN, Tianjin (CN)

(21) Appl. No.: 17/977,045

(22) Filed: Oct. 31, 2022

(30) Foreign Application Priority Data
Aug. 24, 2022 (CN) 202211019992.3

(51) Int. Cl. G06F 11/30; G06F 11/34

(52) U.S. Cl. CPC G06F 11/3034; G06F 11/3086; G06F 11/3452

(57) ABSTRACT

A method for detecting performance of a number of hard disks working under various operating systems, comprising: collecting of performance parameter of hard disks in several pre-determined systems, storing the parameters in a uniform format to obtain unified data; analyzing the unified data to obtain feature parameters of the hard disk; comparing the feature parameters and preset name string to obtain performance data of the hard disk; classifying the hard disk and establishing a performance database by the performance data of the hard disks of different kinds; presenting the data in the performance database with a preset visual tool, the data is regarded detecting results of the hard disks. Performance data from a plurality of systems can thus be presented by the visual tool running across platforms, which improves the scope and immediacy of detection. An apparatus, an electrical device, and a storage medium are also disclosed.

### CROSS-REFERENCE TO RELATED APPLICATION

This application claims priority to China Application No. 202211019992.3, having a filing date of Aug. 24, 2022, filed in China State Intellectual Property Administration, the entire contents of which are hereby incorporate by reference.

### FIELD

The subject matter relates to technologies of detecting performance of a hard disk, and more particularly to a method, an apparatus, an electrical device, and storage medium for detecting performance of hard disks.

### BACKGROUND

Mass storage devices such as hard disks are needed as big data technologies are developing rapidly, safety of data relies on reliability and stability of the hard disks, therefore, technologies of detecting performance of a hard disk have received increasing attention to ensure that the performance of the hard disk meets the needs of reliability and stability.

Different operating systems have different tools for detecting performance of a hard disk, each tool has an application scenario and is incompatible with others. Therefore, an extensible tool with better compatibility is required to overcome the defects.

### SUMMARY

An objective of the present disclosure is achieved by providing method for detecting performance of a hard disk and related devices.

A first aspect of the application provides a method of detecting performance of a hard disk comprising: collecting a single performance parameter of each of multiple hard disks in each of a plurality of pre-determined systems; storing the single performance parameters in a unified format to obtain unified data; analyzing the unified data to obtain feature parameters of the hard disks; comparing the feature parameters and a preset name string to obtain performance data of the hard disks; classifying the hard disks and establishing a performance database by the performance data of each category of the hard disks; presenting results of detection of the hard disks with a preset visual tool, wherein the performance data in the performance database is regarded as the result of the hard disk performances.

The method collects a single performance parameter of a hard disk in different formats for each of a plurality of pre-determined systems and stores the parameters in a uniform format to obtain unified data for analyzing to obtain feature parameters of the hard disk, then selects the performance data of the hard disk according to the detecting requirements and presents the performance data by a preset visual tool capable of running cross platform, which provides an advanced extendibility for the method of detecting performance of a hard disk.

According to further embodiments, the step of collecting a single performance parameter of a hard disk in each of a plurality of pre-determined systems further comprises: collecting performance parameters of the hard disks in each of a plurality of pre-determined systems; establishing a single performance parameter for each of the hard disks according to the name of each of the plurality of pre-determined systems and the performance parameter.

According to further embodiments, storing the single performance parameters in a unified format to obtain unified data comprises: configuring a transcoding facility according to a preset format for converting the single performance parameters into a preset format; obtaining the unified data by inputting the single performance parameters into the transcoding facility.

According to further embodiments, analyzing the unified data to obtain feature parameters of the hard disks comprises: constructing a regular expression according to a preset list of the performance parameters; matching the regular expression and the unified data to obtain a feature parameter for each of the hard disks.

According to further embodiments, comparing the feature parameters and a preset name string to obtain performance data of the hard disks comprises:
a) marking the preset name string as unvisited;
b) selecting one of the unvisited preset name strings, taking it as a present parameter and comparing the present parameter to each of the feature parameters, then taking the feature parameter has same name with the present parameter as the performance data and marking the unvisited preset name string as visited;
c) repeating b) until all the preset name strings are visited, so obtaining multiple performance data.

According to further embodiments, classifying the hard disk and establishing a performance database by the performance data of each category of the hard disks comprises: taking an identification of each of the hard disks as a category of hard disks; establishing a performance database for each category of the hard disks by the performance data of the category of hard disks.

According to further embodiments, the preset visual tool is a collection of programs written in programming languages with cross-platform properties.

According to a second aspect of the application, an apparatus for detecting performance of a hard disk is provided, comprising: a collecting unit configured for collecting single performance parameters of multiple hard disks in each of a plurality of pre-determined systems; an analyzing unit configured for storing the single performance parameters in a unified format to obtain unified data, analyzing the unified data to obtain feature parameters of the hard disks, comparing the feature parameters and a preset name string to obtain performance data of the hard disks, and classifying the hard disks and establishing a performance database by the performance data of each category of the hard disks; a storage unit configured for storing the single performance parameters, the unified data, the feature parameters, and the performance data, and

a visual unit configured for presenting results of detecting performance of the hard disks with a preset visual tool, wherein the performance data in the performance database is regarded as the results.

According to a third aspect of the application, an electronic device comprises: a storage device configured for storing computer readable instructions, and a processer configured for executing the computer readable instructions to perform the method of detecting performance of hard disks abovementioned.

According to a fourth aspect of the application, a computer readable medium storing computer readable instructions being executed by a processer in an electronic device to implement the method abovementioned.

### BRIEF DESCRIPTION OF THE DRAWINGS

Implementations of the present technology will now be described, by way of example only, with reference to the attached figures.

FIG. 1 is a flow chart of a method for detecting performance of hard disks according to one preferred embodiment of the present disclosure;

FIG. 2 is a functional module diagram of an apparatus for detecting performance of hard disks according to one preferred embodiment of the present disclosure;

FIG. 3 shows SMART data provided by an embodiment of a method of the present disclosure;

FIG. 4 shows FIO data provided by an embodiment of a method of the present disclosure;

FIG. 5 shows bad sector data provided by an embodiment of a method of the present disclosure;

FIG. 6 shows an initializing interface of a visual tool provided by an embodiment of the present disclosure;

FIG. 7 shows results presented by the visual tool according to a third embodiment of the present disclosure;

FIG. 8 is a functional module diagram of an apparatus for detecting performance of hard disks according to a further embodiment of the present disclosure;

FIG. 9 is a schematic diagram of the structure of an electronic device for detecting performance of hard disks according to a further embodiment of the present disclosure.

### DETAILED DESCRIPTION

It will be appreciated that for simplicity and clarity of illustration, where appropriate, reference numerals have been repeated among the different figures to indicate corresponding or analogous components. The description is not to be considered as limiting the scope of the embodiments described herein. The drawings are not necessarily to scale and the proportions of certain parts may be exaggerated to better illustrate details and features of the present disclosure.

It should be understood that, the terms “first” and “second” are used to distinguish between elements and are not used to denote a particular order or imply a number of technical features, therefore, unless specifically defined, features described as “first” and “second” may expressly or implicitly include one or more of the stated features. In the description of the present application, “plurality” means “two or more”, unless otherwise expressly and specifically defined.

In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described.

The term “comprising,” when utilized, means “including, but not necessarily limited to”; it specifically indicates open-ended inclusion or membership in the so-described combination, group, series, and the like.

With reference to the figures, a detailed description of the hereinafter described embodiments of the disclosure is presented herein by way of exemplification and not as limitation.

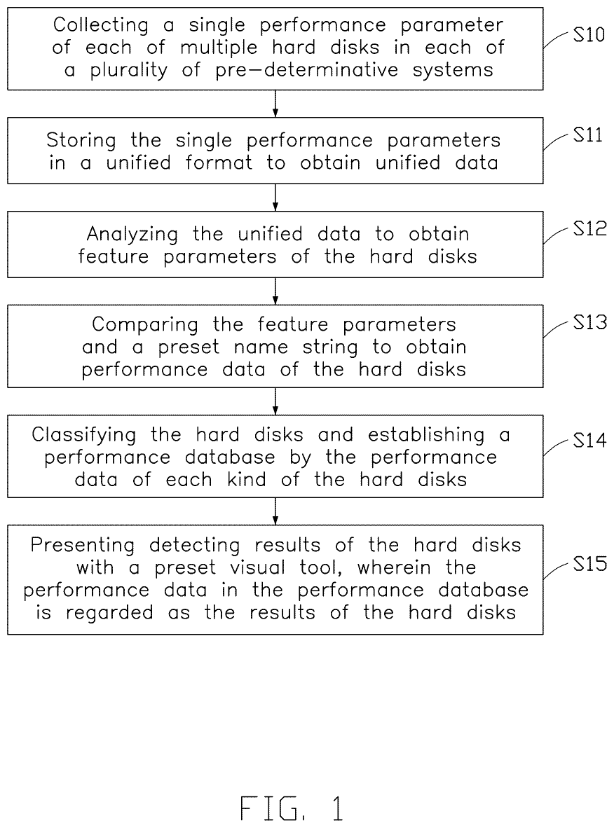

Referring to FIG. 1, a method for detecting performance of hard disks is provided, the method can be applied to one or more electronic devices. The electronic device is a device automatically performing numerical calculations and/or information processing according to pre-set or stored instructions, the electronic device comprises hardware including but not limited to for example microprocessor, application specific integrated circuit (ASIC), field—programmable gate array (FPGA), digital signal processor (DSP), and embedded device.

The electronic devices can be selected from a personal computer (PC), a tablet, a smartphone, a personal digital assistant (PDA), a playstation, an internet protocol television (IPTV), a smart wearable device, or any other electronic device capable of human-computer interaction.

The electronic devices further comprise network devices and/or user devices, the network devices including but not limited to a single network server, a server group comprised of multiple network servers or a cloud computing arrangement comprised of multiple host computers or network servers according to cloud computing.

The electronic devices are connected in a network including but not limited to internet, wide area network, metropolitan area network, local area network, and virtual private network (VPN).

Referring to FIG. 1, a flow chart of a method for detecting performance of hard disks according to one preferred embodiment is shown, steps of the method can be performed in different order and some of the steps can be skipped.

S10, collecting a single performance parameter of multiple hard disks in each of a plurality of pre-determined systems.

According to an embodiment, the collecting a single performance parameter of each of the multiple hard disks in each of a plurality of pre-determined systems further comprises:
collecting performance parameters of the hard disks in each of a plurality of pre-determined systems;
establishing single performance parameters for the hard disks according to the name of each of the plurality of pre-determined systems and the performance parameters.

In this embodiment, the plurality of pre-determined systems refer to different operating systems that the hard disks running in, each of the plurality of pre-determined systems have respective data collecting tools, and different tools display the performance parameter of the hard disks in different forms. For example, in WINDOWS, the performance data of the hard disk's health collected by a detecting tool of Smartmontool-win32 are displayed as codes in a Powershell window and the performance data of the hard disk's health collected by a detecting tool of CrystalDistlnfo are displayed as Chinese characters in a graphic interface. Therefore, a preset tool is required for collecting the performance parameter of the hard disk's health in different operating systems to comprehensively characterize the performance of the hard disks.

According to the embodiment, the preset tool refers to a program running in the pre-determined systems for collecting performance parameters of the hard disks. For example, in LINUX, the preset tool can be selected from Smartmontools, fio, hdparm, nvme-cli, sg3_utils, and any other existing tools; in WINDOWS, the preset tool can be selected from CrystalDistlnfo, Cry stalDi skMark, Smartmontools-win32, fio-x64-windows, and any other existing tool, not limited in this application.

According to the embodiment, the performance parameter includes but not limited to SMART data, FIO data, bad sector data, and auxiliary data. The SMART data refers to data of a Self—Monitoring Analysis and Reporting Technology, and specifically comprises data of conditions of a magnetic head unit of the hard disk, a temperature of the hard disk, information of surface medium material, conditions of disk motor and driver system, and circuit information in the hard disk; the FIO data comprises data rate in/out per second (IOPS), bandwidth data, response time, and so on. The bandwidth data indicates the total amount of data the hard disk can process per second, the response time indicates a time taken by the hard disk from initiating a read/write request to completing the read/write request. The hard disk is divided into a plurality of sector blocks, each sector block has an index, and the bad sector data represents an index of fault sector blocks in the hard disk. The auxiliary data is applied to supplement the missing information about other performance parameters, which comprises plug information, abnormal link Information, and other information of the performance of the hard disk.

According to the embodiment, the performance parameters can be labelled by the name of the pre-determined systems, and each performance parameter and the respective label can be stored as a single performance parameter, an original database can be established from all the single performance parameters.

Therefore, by collecting various single performance parameters of one hard disk in a plurality of pre-determined systems, the various single performance parameters can comprehensively characterize the performance of the hard disk, which improves comprehensiveness and expandability for detection of the hard disk.

S11, storing the single performance parameters in a unified format to obtain unified data.

The single performance parameters collected in different operating systems by different tools have different formats, for example, the formats of the single performance parameters comprise TXT, Xls, MarkDown, Json, XML, and so on. The single performance parameters can be stored in a unified format to obtain unified data.

According to a further embodiment, the step of storing the single performance parameters in a unified format to obtain unified data comprises:
configuring a transcoding facility according to a preset format for converting the single performance parameters into a preset format;
obtaining the unified data by inputting the single performance parameters into the transcoding facility.

In the embodiment, the transcoding facility is configured according to the preset format for converting the single performance parameters into a preset format. For example, a preset Json format conversion tool is set as the transcoding facility if the preset data format is Json format, the preset Json format conversion tool may be the jsonlib tool in the Java language, j son interface in the Python language, or any other existing Json format conversion tools; a preset XML, format conversion tool is set as the transcoding facility if the preset data format is in XML format, the preset XML format conversion tool may be the Xstream in the Java language, XML interface in the Python language, or any other existing XML format conversion tools, which is not limited here.

In this embodiment, the unified data can be obtained by inputting the single performance parameters into the transcoding facility.

Therefore, the single performance parameters in different formats are converted to a unified format for subsequent analyzing, which improves the efficiency for detecting performance of the hard disk.

S12, analyzing the unified data to obtain feature parameters of the hard disks.

According to a further embodiment, the step of analyzing the unified data to obtain feature parameters of the hard disks comprises:
constructing a regular expression according to a preset list of the performance parameters;
matching the regular expression and the unified data to obtain feature parameters of the hard disks.

According to the embodiment, the preset list of the performance parameters is used for recording parameter names relevant to the performance of the hard disks, the regular expression is used for extracting data containing the parameter name from the unified data. For example, the preset performance parameter can be named IOPS, then the regular expression is *\bIOPS\b, and the data containing a character string of “IOPS” can be selected from all the unified data. If the preset performance parameter is named as “Temperature”, then the regular expression is *\bTemperature\b, and the data containing a character string of “Temperature” can be selected from all the unified data.

In this embodiment, the unified data can be screened by the regular expression to obtain a plurality of performance parameters.

Therefore, the regular expression is constructed according to a preset list of the performance parameters, the unified data is screened by the regular expression to obtain object data for each performance parameter, then data related to the performance of the hard disks can be selected from the unified data and the accuracy of detection of the performance of the hard disks can be improved.

S13, comparing the feature parameters and a preset name string to obtain performance data of the hard disks.

According to a further embodiment, the step of comparing the feature parameters and a preset name string to obtain performance data of the hard disks comprises:
a) marking the preset name string as unvisited, the preset name string being used for representing the name of the feature parameter which satisfies a preset detecting requirement, for example, if the preset detecting requirement is “detecting a I/O per second data”, then the preset name string is TOPS; the preset detecting requirement is “detecting a peak rate of reading/writing”, then the preset name string can be Topspeed; the preset detecting requirement is “detecting a temperature of the hard disk”, then the preset name string can be Temperature;
b) selecting one of the unvisited preset name strings, taking it as a present parameter and comparing the present parameter to each of the feature parameters, then taking the feature parameter has same name with the present parameter as performance data and marking the unvisited preset name string as visited;
c) repeating b) until all the preset name strings are visited, then multiple performance data is thereby obtained.

Therefore, the name strings are set according to the preset detecting requirement, the feature parameters are compared to the preset name strings to select the feature parameters of the hard disks which satisfy the preset detecting requirement as the performance data of the hard disks, which improves flexibility of detection of performance of the hard disks.

S14, classifying the hard disks and establishing a performance database by the performance data of each category of the hard disks.

According to a further embodiment, the step of classifying the hard disks and establishing a performance database by the performance data of each category of the hard disks comprises:
taking an identification of each of the multiple hard disks as a category of the hard disks;
establishing a performance database for each category of the hard disks by the performance data of the category of hard disks.

In this embodiment, the identification of the hard disk can be any relevant information such as its brand or serial number, which is not limited here. For example, for a hard disk has a brand “brand 1” and a serial number “SN2”, the category of the hard disk can be “brand 1”, “SN2”, or “brand 1+SN2”.

In this embodiment, the performance data of hard disks of same category can be stored to establish a performance database. For example, a hard disk of category “brand 1+SN2” has performance data A, then the performance data A can be stored to establish a performance database marked with “brand 1+SN2”.

Therefore, the hard disks are classified according to the identification and the performance database is established by the performance data of the hard disks of the same category, which allows the performance data of the hard disks of the same category to be stored together and provides an easy way to display results of detecting performance of the hard disks.

S15, presenting results of detection of the hard disks with a preset visual tool, wherein the performance data in the performance database is regarded as the results.

According to an alternative embodiment, the preset visual tool is a collection of programs written in programming languages with cross-platform properties, such as Python, Java, PHP, or any other suitable programming language, which is not limited here.

Therefore, the preset visual tool written in programming languages with cross-platform properties can be used to present the results of detection in any operating system, which improves the flexibility of presenting the results.

The method for detecting performance of hard disks collects single performance parameters of multiple hard disks in different formats for each of a plurality of pre-determined systems and stores the parameters in a uniform format to obtain unified data for analysis, to obtain feature parameters of the hard disks, then selects the performance data of the hard disks according to the detecting requirements and presents the performance data by a preset visual tool capable of running cross platform, which provides an advanced extendibility for the method for detecting performance of a hard disk.

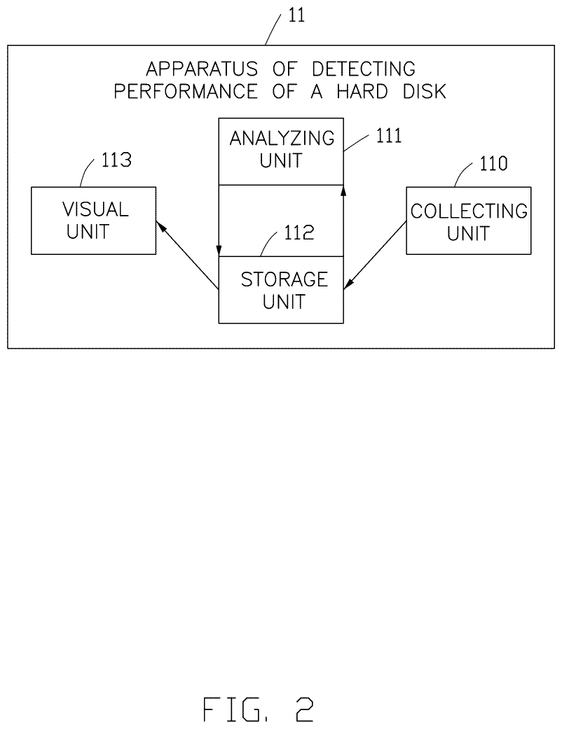

Referring to FIG. 2, a functional module diagram of an apparatus for detecting performance of hard disks according to one preferred embodiment of the present disclosure is provided. The apparatus 11 for detecting performance of hard disks comprises a collecting unit 110, an analyzing unit 111, a storage unit 112, and a visual unit 113. These units or modules refer to a program segment store in a storage device and being executable by a processor to complete a preset function. The function of each module/unit will be described in detail in following embodiments.

According to a further embodiment, the collecting unit 110 is configured for collecting the single performance parameters of the hard disks in each of a plurality of pre-determined systems.

According to a further embodiment, the collecting unit 110 comprises at least one preset data collecting tool for collecting the single performance parameters of the hard disks in each of a plurality of pre-determined systems, and collecting the single performance parameters of the hard disks in each of a plurality of pre-determined systems by the collecting unit 110 comprises:
collecting performance parameters of the hard disks in each of a plurality of pre-determined systems;
establishing single performance parameters for the hard disks according to the name of each of the plurality of pre-determined systems and the performance parameter.

In this embodiment, a plurality of pre-determined systems refer to different operating systems that the hard disks running in, each of the plurality of pre-determined systems have respective data collecting tools, and different tools display the performance parameters of the hard disks in different forms. For example, in WINDOWS, the performance data of the hard disk's health collected by a detecting tool of Smartmontool-win32 are displayed as codes in a Powershell window and the performance data of the hard disk's health collected by a detecting tool of CrystalDistlnfo are displayed as Chinese characters in a graphic interface. Therefore, a preset tool is required to collecting the performance parameter of the hard disk's health in different operating systems to comprehensively characterize the performance of the hard disk.

According to the embodiment, the preset data collecting tool refers to a program running in the pre-determined systems for collecting performance parameters of hard disks. For example, in Linux, the preset tool can be selected from Smartmontools, fio, hdparm, nvme-cli, sg3_utils, and any other existing tools; in Windows, the preset tool can be selected from CrystalDistlnfo, CrystalDiskMark, Smartmontools-win32, fio-x64-windows, and any other existing tools, which is not limited in this application.

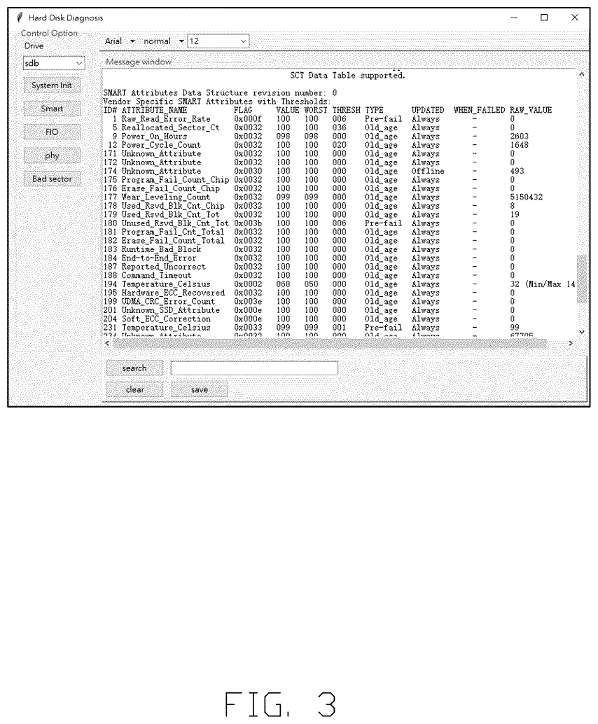

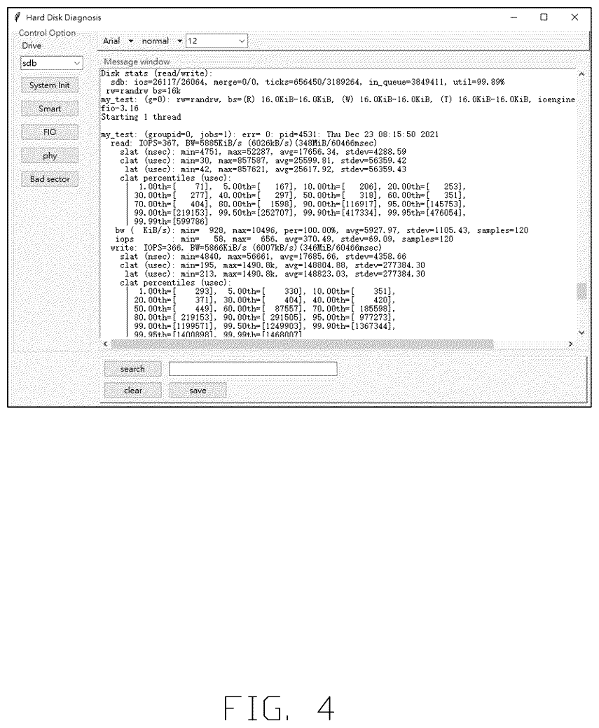

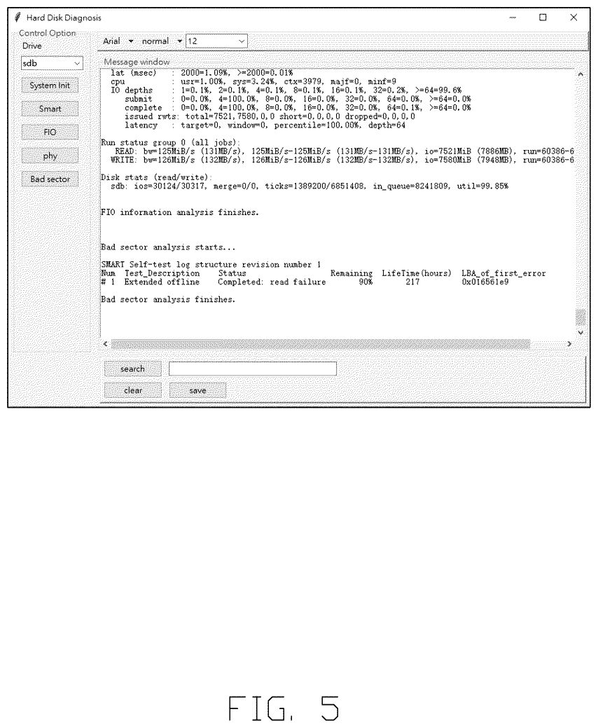

According to the embodiment, the performance parameters including but not limited to SMART data, FIO data, bad sector data, and auxiliary data. The SMART data refers to data of a Self—Monitoring Analysis and Reporting Technology, and specifically comprises data of conditions of a magnetic head unit of the hard disk, a temperature of the hard disk, information of surface medium material, conditions of disk motor and a driver system, and circuit information in the hard disk. FIG. 3 shows SMART data; the FIO data comprises a drive letter of the hard disk, a number of test threads, IOPS rate of the hard disk, a peak rate of speed of reading/writing, and so on. FIG. 4 shows FIO data; the hard disk is divided into a plurality of sector blocks, each sector block has an index, and the bad sector data represents an index of fault sector blocks in the hard disk. FIG. 5 shows bad sector data; the auxiliary data comprises plug information, abnormal link Information, and other information of the performance of the hard disk.

According to the embodiment, each of the performance parameters can be labelled by a name of each of the pre-determined systems, then each performance parameter and the respective label can be stored as a single performance parameter.

According to a further embodiment, the analyzing unit 111 is configured for storing the single performance parameters in a unified format to obtain unified data.

The single performance parameters collected in different operating systems by different tools have different formats, for example, the formats of the single performance parameters comprise TXT, Xls, MarkDown, Json, XML, and so on. The single performance parameters can be stored in a unified format to obtain unified data.

According to a further embodiment, storing the single performance parameters in a unified format to obtain unified data further comprises:
configuring a transcoding facility according to a preset format for converting the single performance parameters into a preset format;
obtaining the unified data by inputting the single performance parameters into the transcoding facility.

In the embodiment, the transcoding facility is configured according to the preset format for converting the single performance parameters into a preset format. For example, a preset Json format conversion tool is set as the transcoding facility if the preset data format is Json format, the preset Json format conversion tool may be the jsonlib tool in the Java language, j son interface in the Python language, or any other existing Json format conversion tools; a preset XML, format conversion tool is set as the transcoding facility if the preset data format is XML format, the preset XML format conversion tool may be the Xstream in the Java language, XML interface in the Python language, or any other existing XML format conversion tools, which is not limited here.

In this embodiment, the unified data can be obtained by inputting the single performance parameters into the transcoding facility.

According to an alternative embodiment, the analyzing unit 111 is configured for analyzing the unified data to obtain feature parameters of the hard disks.

In specific, analyzing the unified data to obtain feature parameters of the hard disks by the analyzing unit 111 comprises:
constructing a regular expression according to a preset list of the performance parameters;
matching the regular expression and the unified data to obtain the feature parameters of the hard disks.

According to the embodiment, the preset list of the performance parameters is used for recording parameter names related to the performance of the hard disks, the regular expression is used for extracting data containing the parameter name from the unified data. For example, if the preset performance parameter is named IOPS, then the regular expression is *\bIOPS\b, and the data containing a character string of “TOPS” can be selected from all the unified data. If the preset performance parameter is named “Temperature”, then the regular expression is *\bTemperature\b, and the data containing a character string of “Temperature” can be selected from all the unified data.

In this embodiment, the unified data can be screened by the regular expression to obtain a plurality of performance parameters. Specifically, the regular expression is used to match with each of the unified data, if the unified data comprises the character string of the regular expression, a result of success is returned and the unified data can be taken as a feature parameter; if the unified data does not comprise the character string of the regular expression, a result of failure is returned and the matching process should be continued until all the unified data is processed and multiple feature parameters are obtained.

According to a further embodiment, the analyzing unit 111 is further configured for comparing the feature parameter and a preset name string to obtain performance data of the hard disks.

According to a further embodiment, comparing the feature parameter and a preset name string to obtain performance data of the hard disks by the analyzing unit 111 comprises:
a) marking a preset name string as unvisited, the preset name string is used for representing the name of the feature parameter satisfying a preset detecting requirement, for example, the preset detecting requirement may be “detecting I/O rate per second data”, then the preset name string is TOPS; the preset detecting requirement is “detecting a peak speed of reading/writing”, then the preset name string can be Topspeed; if the preset detecting requirement is “detecting a temperature of the hard disk”, then the preset name string can be Temperature;
b) selecting one of the unvisited preset name strings, taking it as a present parameter and comparing the present parameter to each of the feature parameters, then taking the feature parameter which has same name as the present parameter as performance data and marking the unvisited preset name string as visited;
c) repeating b) until all the preset name strings are visited, then multiple performance data is obtained.

According to an alternative embodiment, the analyzing unit 111 is further configured for classifying the hard disks and establishing a performance database by the performance data of each kind of the hard disks.

According to a further embodiment, classifying the hard disks and establishing a performance database by the performance data of each category of the hard disks by the analyzing unit 111 comprises:
taking an identification of a hard disk as a category of hard disks;
establishing a performance database for each category of hard disks by the performance data of the category of hard disks.

In this embodiment, the identifications of the hard disks can be any relevant information such as its brand or serial number, which is not limited here. For example, for a hard disk labelled “brand 1” and a serial number “SN2”, the category of the hard disk can be “brand 1”, “SN2”, or “brand 1+SN2”.

In this embodiment, the performance data of hard disks of same category can be stored to establish a performance database. For example, a hard disk of category “brand 1+SN2” can have performance data A, then the performance data A can be stored to establish a performance database labelled “brand 1+SN2”.

According to an alternative embodiment, the storage unit 112 is configured for storing the single performance parameters, the unified data, the feature parameters, and the performance data. The storage unit 112 is selected from database of Elasticsearch, database of MySql, database of SqlLite, or any other existing data storage tool, which is not limited here.

According to an alternative embodiment, the visual unit 113 is configured for presenting results of the hard disks detection with a preset visual tool, wherein the performance data in the performance database is regarded as the results.

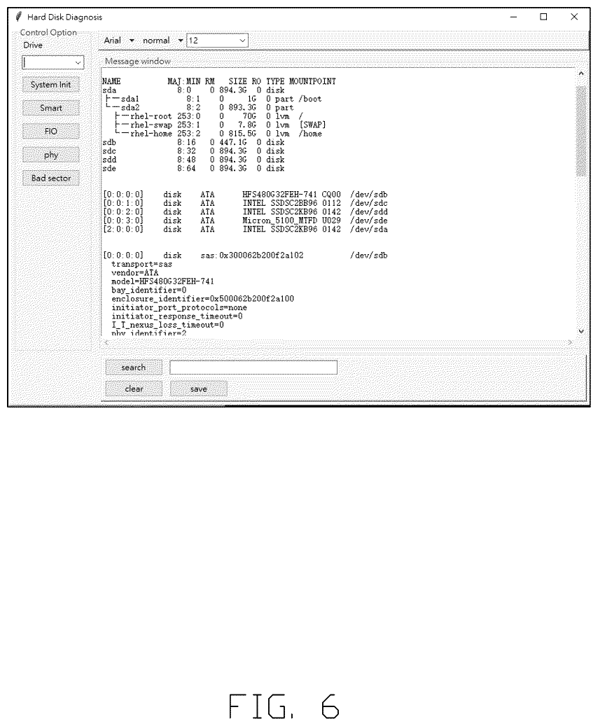

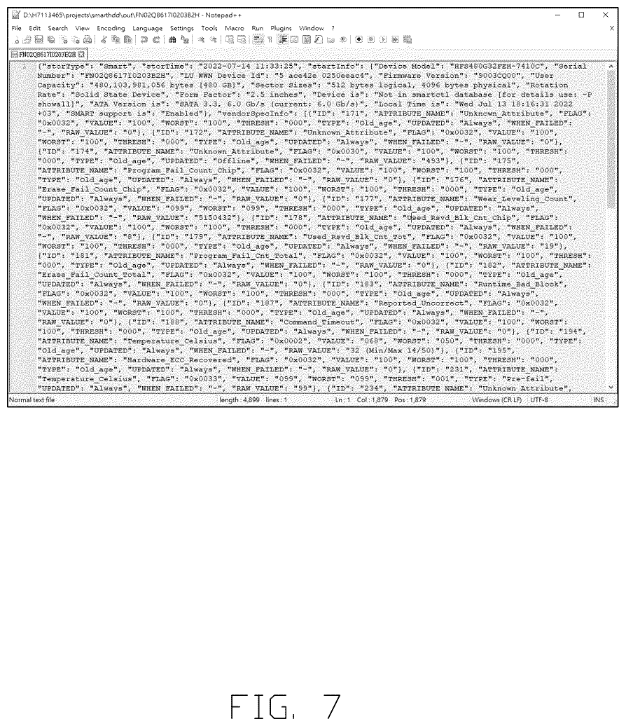

According to an alternative embodiment, the preset visual tool is a collection of programs written in programming languages with cross-platform properties, such as Python, Java, PHP, or any other suitable programming language, which is not limited here. For example, FIG. 6 shows an initialization interface of the preset visual tool, and FIG. 7 shows the detected results presented by the visual tool according to a third embodiment of the present disclosure;

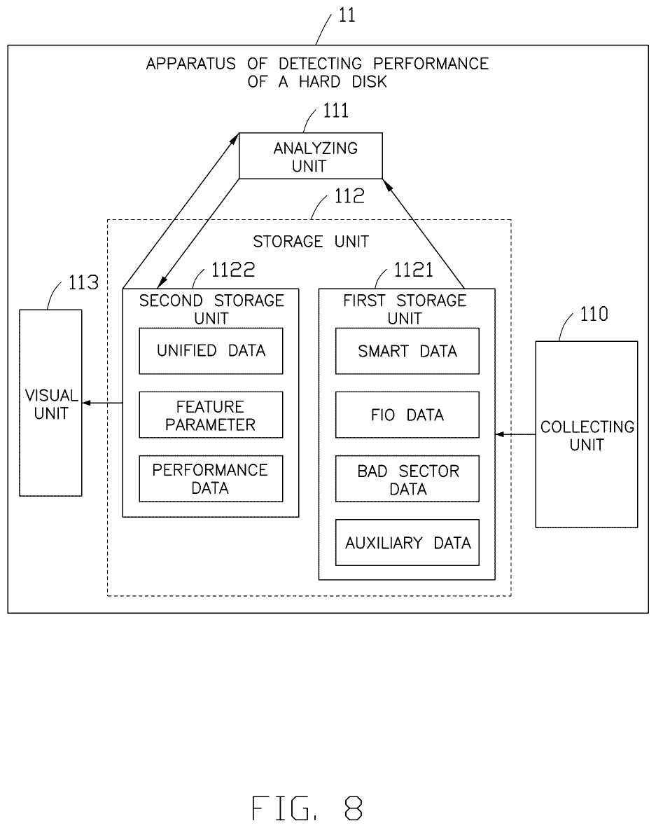

Referring to FIG. 8, according to a further embodiment, the storage unit 112 comprises a first storage unit 1121 and a second storage unit 1122, each of the first storage unit 1121 and the second storage unit 1122 can be selected from database of Elasticsearch, database of MySql, database of SqlLite, or any other existing data storage tool, which is not limited here. The first storage unit 1121 is configured for receiving and storing the single performance parameters of the hard disks from the collecting unit 110, the single performance parameters comprises SMART data, FIO data, bad sector data, auxiliary data, and so on; the first storage unit 1121 is further configured for sending the single performance parameters to the analyzing unit 111 for analyzing; the second storage unit 1122 is configured for receiving and storing the unified data, the feature parameters, and the performance parameters of the hard disks from the analyzing unit 111, the performance parameters are stored in the performance database, the performance database is configured for sending the performance data to the visual unit 113 for presenting the results of the performance of the hard disks as detected.

The apparatus for detecting performance of hard disks collects a single performance parameter of a hard disk in different formats for each of a plurality of pre-determined systems and stores the parameters in a uniform format to obtain unified data for analyzing to obtain feature parameters of the hard disk, then selects the performance data of the hard disk according to the detecting requirements and presents the performance data by a preset visual tool capable of running cross platform, which provides an advanced extendibility for the method of detecting performance of a hard disk.

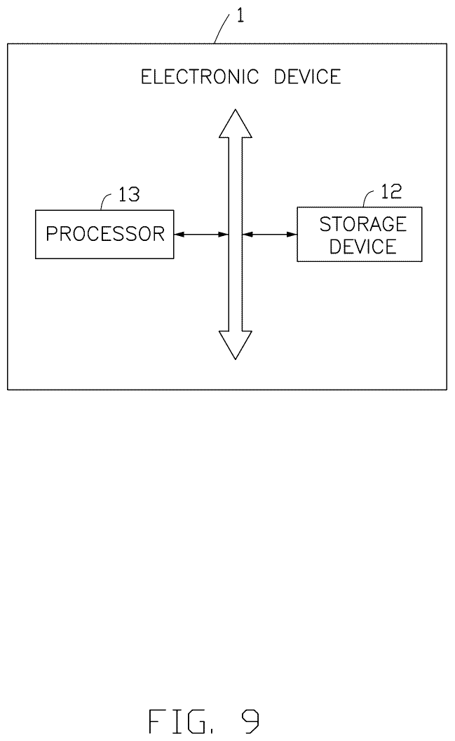

Referring to FIG. 9, a schematic diagram of the structure of an electronic device of detecting performance of a hard disk according to a further embodiment of the present disclosure is provided. The electronic device 1 comprises a storage device 12 and a processer 13, the storage device 12 is configured for storing computer readable instructions, the processor 13 is configured for executing the computer readable instructions to perform the method for detecting performance of hard disks according to any of the above-mentioned embodiments.

According to a further embodiment, the electronic device 1 further comprises a bus and computer programs stored in the storage device 12 and being executable by a processor 13, such as a program for detecting performance of hard disks.

The electronic device 1 is shown in FIG. 9, only the storage device 12 and the processor 13 of the electronic device 1 are illustrated. The structure of the electronic device 1 shown in FIG. 9 should not be seen as limitation to the electronic device 1, the electronic device 1 may comprise more or less components or assembly of some certain components, and in further embodiments, the electronic device 1 may have a different arrangement of different components.

Referring to FIG. 1, the storage device 12 of the electronic device 1 stores multiple computer readable instructions to execute a method for detecting performance of a hard disk, the processer 13 can execute multiple instructions to perform following steps:
collecting a single performance parameter of a hard disk in each of a plurality of pre-determined systems;
storing the single performance parameters in a unified format to obtain unified data;
analyzing the unified data to obtain feature parameters of the hard disk;
comparing the feature parameter and a preset name string to obtain performance data of the hard disk;
classifying the hard disk and establishing a performance database by the performance data of each type of hard disks;
presenting results of detection relating to the hard disks with a preset visual tool, wherein the performance data in the performance database is regarded as the results.

Specifically, the processor 13 executes the instructions according to the embodiment shown in FIG. 1, which will not be repeated here.

Those skilled in the art should be noted that, FIG. 9 shows only one example of the electronic device 1, which should not be seen as a limitation to the electronic device 1. The electronic device 1 can have a bus-type structure or a star-type structure, more or less hardware/software, and different arrangements. For example, the electronic device 1 can comprise input/output elements, internet access device, or any other suitable devices.

It should be noted that, the electronic device 1 is merely a preferred embodiment of the present invention, it is not intended to limit the present invention. A person skilled in the art may make various modifications and changes to the present invention. Any modification, equivalent replacement, improvement and the like made within the spirit and principle of the present invention shall all be included in a scope of protection of the present invention.

The storage device 12 includes at least one type of readable storage medium, the readable storage medium can include volatile and nonvolatile memory, removable and non-removable media implemented in any method or technology for storage of information, such as computer readable instructions, data structures, program modules, or other data, for example, a flash memory, a mobile hard disk, a multimedia card, a card type memory such as a SD card or a DX card, a magnetic memory, a magnetic disk, or an optical disk. According to a further embodiment, the storage device 12 can be an interior storage unit such as a mobile hard disk of the electronic device 1 and/or an external storage unit such as a plug-in removable hard disk, a smart media card, a secure digital card, a flash card, and so on. Further, the storage device 12 is configured for storing applications installed on the electronic device 1 and various data such as codes of the program for detecting the performance of the hard disk, and temporarily storing the data that is going to be output or has been output.

In some embodiments, the processor 13 may be composed of an integrated circuit, for example, may be composed of a single packaged integrated circuit, or may be composed of a plurality of integrated circuits of same function or different functions. The processor 13 can include one or more central processing units (CPUs), a microprocessor, a digital processing chip, a graphics processor, and various control chips. The processor 13 is a control unit of the electronic device 1, which connects various components of the electronic device 1 using various interfaces and lines. By running or executing a computer program or modules stored in the storage device 12, and by invoking the data stored in the storage device 601, the processor 13 can perform various functions of the electronic device 1 and process data of the electronic device 1.

In a further embodiment, the processor 13 can execute an operating system and various types of applications installed in the electronic device 1. The processor 13 execute the applications to implement the method for detecting the performance of the hard disk according the above-mentioned embodiments, such as the method shown in FIG. 1.

In an embodiment, the computer program can be divided into one or more modules/units, the one or more modules/units being stored in the storage device 12 and executed by the processer 13 to implement the method of the application. The one or more modules/units refers to a series of program segments capable of performing a preset function and can be used to describe an implementation of the computer program in the electronic device 1. For example, the computer program can be divided into a collecting unit 110, an analyzing unit 111, a storage unit 112, and a visual unit 113.

The above-described integrated units implemented in a form of software function modules can be stored in a computer readable storage medium. The above software function modules are stored in a storage medium, and include a plurality of instructions for causing a computing device (which may be a personal computer, or a network device, etc.) or a processor to execute the method according to various embodiments of the present disclosure.

The module/unit integrated in the electronic device 1, when implemented in the form of software functional modules as independent products, may be stored in a computer readable storage medium. Based on such understanding, the present disclosure implements all or part of the processes in the foregoing embodiments, and may also be completed by a computer program to instruct related hardware. The computer program may be stored in a computer readable storage medium. The methods of the various embodiments described above may be implemented when the program is executed by the processor.

The computer program includes computer program codes, which may be in the form of source code, object code form, executable file, or some intermediate form. The computer readable medium may include any entity or device capable of carrying out the computer program codes, such as a recording medium, a USB flash drive, a removable hard disk, a magnetic disk, an optical disk, a computer memory, and a read-only memory (ROM).

Further, the computer readable medium may include a program storage area and a data storage area, wherein the storage program area may store an operating system, an application required for at least one function, and the like. The storage data area may store data created during use of the electronic device 1.

In this application, the blockchain referred to is a new application model of computer technology such as distributed data storage, peer-to-peer transmission, consensus mechanism, and cryptographic algorithms. Blockchain is essentially a decentralized database of a string of data blocks generated using a cryptographic method of correlation, each data block contains information about a batch of network transactions for verifying the validity of its information (forgery-proof) and generating the next block. Blockchain can include a blockchain underlying platform, a platform product service layer, and an application service layer.

The bus can be a Peripheral Component Interconnect (PCI) bus or an Extended Industry Standard Architecture (EISA) bus, and can be divided into address bus, data bus, control bus, and so on. For illustration, FIG. 9 shows only one arrow to represent the bus, but it does not mean that there is only one bus or one type of bus. The bus is configured for communication between the storage device 12 and at least one processor 13.

Although it is not shown, the electronic device 1 may further include a power supply (such as a battery) for powering various components. In some embodiments, the power supply may be logically connected to the at least one processor 13 through a power management device, thereby, the power management device manages functions such as charging, discharging, and power management. The power supply may include one or more of a DC or an AC power source, a recharging device, a power failure detection circuit, a power converter or inverter, a power status indicator, and the like. The electronic device 1 may further include various sensors, such as a BLUETOOTH module, a WI-FI module, and the like, and details are not described herein.

Further, electronic device 1 further comprises a network interface comprising a wire interface and/or a wireless interface, such as a BLUETOOTH module and/or a WI-FI module, for communication between the electronic device 1 and other electronic devices.

Optionally, the electronic device 1 further comprises a user interface comprising a display and/or an input unit such as a keyboard, optionally, the user interface can be wired or wireless. Alternatively, in further embodiments, the display may be an LED display, an LCD display, a touchscreen LCD display, an OLED (Organic Light-Emitting Diode) touch device, and so on. The display may also be referred as a display unit for displaying information processed in the electronic device 1 and a visual user interface.

According to a further embodiment, a computer readable medium (not shown) is provided, the computer readable medium stores computer readable instructions which can be executed by the processer in the electronic device to implement the method for detecting performance of a hard disk according to any embodiment of the application.

It should be noted that the above embodiments are only for explaining the technical solutions of the present disclosure and are not intended to be limiting, and the present disclosure describes preferred embodiments. Modifications or equivalents can be made without departing from the spirit and scope of the present disclosure.

In the several embodiments provided by the present disclosure, it should be understood that the disclosed system, apparatus, and method may be implemented in another manner. For example, the device embodiments described above are merely illustrative. For example, the division of the modules is only a logical function division, and the actual implementation may have another manner of division.

The modules described as separate components may or may not be physically separated, and the components displayed as modules may or may not be physical modules, that is, may be located in one place, or may be distributed in multiple network modules. Some or all of the modules may be selected according to actual needs to achieve the purpose of the disclosure.

In addition, each functional module in each embodiment of the present disclosure may be integrated into one processing unit, or each unit may exist as a standalone unit, or two or more modules may be integrated into one unit. The above integrated unit can be implemented in the form of hardware or in the form of hardware plus software function modules.

It should be apparent to those skilled in the art that the present disclosure is not limited to the details of the above-described exemplary embodiments, and the present disclosure can be embodied in other specific forms without departing from the spirit or essential characteristics of the present disclosure. Therefore, the present embodiments are to be considered as illustrative and not restrictive, and the scope of the present disclosure is defined only by the appended claims, all changes in the meaning and scope of equivalent elements are included in the present disclosure. Any accompanying drawings in the claims should not be construed as limiting the claim. In addition, it is to be understood that the word “including” does not exclude other elements or steps. A plurality of modules or devices recited in the system claims can also be implemented by a unit or device by software or hardware. The particular ordering of words does not denote any particular order.

It should be noted that the above embodiments are only for explaining the technical solutions of the present disclosure and are not intended to be limiting, and the present disclosure describes preferred embodiments. Modifications or equivalents can be made without departing from the spirit and scope of the present disclosure.

What is claimed is:

1. A method for detecting performance of a hard disk comprising:
collecting a single performance parameter of each of multiple hard disks in each of a plurality of pre-determined systems;
storing the single performance parameters in a unified format to obtain unified data;
analyzing the unified data to obtain feature parameters of the hard disks;
comparing the feature parameter and a preset name string to obtain performance data of the hard disks;
classifying the hard disks and establishing a performance database by the performance data of each category of the hard disks;
presenting results of detection of the hard disks with a preset visual tool, wherein the performance data in the performance database is regarded as the result of the hard disk performances.

2. The method of claim 1, wherein collecting a single performance parameter of hard disks in each of a plurality of pre-determined systems further comprises:
collecting performance parameters of the hard disks in each of a plurality of pre-determined systems;
establishing a single performance parameter for each of the hard disks according to the name of each of the plurality of pre-determined systems and the performance parameter.

3. The method of claim 1, wherein storing the single performance parameters in a unified format to obtain unified data comprises:
configuring a transcoding facility according to a preset format for converting the single performance parameters into a preset format;
obtaining the unified data by inputting the single performance parameters into the transcoding facility.

4. The method of claim 1, wherein analyzing the unified data to obtain feature parameters of the hard disks comprises:
constructing a regular expression according to a preset list of the performance parameters;
matching the regular expression and the unified data to obtain a feature parameter for each of the hard disks.

5. The method of claim 1, wherein step of comparing the feature parameters and a preset name string to obtain performance data of the hard disks comprises:
a) marking the preset name string as unvisited;
b) selecting one of the unvisited preset name strings, taking it as a present parameter and comparing the present parameter to each of the feature parameters, then taking the feature parameter has same name with the present parameter as the performance data and marking the unvisited preset name string as visited;
c) repeating b) until all the preset name strings are visited, then multiple performance data is obtained.

6. The method of claim 1, wherein step of classifying the hard disks and establishing a performance database by the performance data of each category of the hard disks comprises:
taking an identification of each of the hard disks as a category of hard disks;
establishing a performance database for each category of the hard disks by the performance data of the category of hard disks.

7. The method of claim 1, wherein the preset visual tool is a collection of programs written in programming languages with cross-platform properties.

8. An apparatus for detecting performance of a hard disk comprising:
a collecting unit configured for collecting single performance parameters of multiple hard disks in each of a plurality of pre-determined systems;
an analyzing unit configured for storing the single performance parameters in a unified format to obtain unified data, analyzing the unified data to obtain feature parameters of the hard disks, comparing the feature parameters and a preset name string to obtain performance data of the hard disks, and classifying the hard disks and establishing a performance database by the performance data of each category of the hard disks;
a storage unit configured for storing the single performance parameters, the unified data, the feature parameter, and the performance data, and
a visual unit configured for presenting results of detecting performance of the hard disks with a preset visual tool, wherein the performance data in the performance database is regarded as the results.

9. An electronic device comprising:
a storage device configured for storing computer readable instructions, and
a processer configured for executing the computer readable instructions to perform the method for detecting performance of hard disks of claim 1.

10. A computer readable medium storing computer readable instructions being executed by a processer in an electronic device to implement the method of claim 1.
